(19) United States
(12) Patent Application Publication
(10) Pub. No.: US 2026/0293711 A1
(43) Pub. Date: Sep. 24, 2026

(54) PACKAGE FOR SIDE-BY-SIDE DIES AND PARTIALLY OVERLAPPING INTERCONNECTED SUBSTRATES

(71) Applicant: QUALCOMM Incorporated, San Diego, CA (US)

(72) Inventors: Aniket PATIL, San Diego, CA (US); Zhijie WANG, San Diego, CA (US); Manuel ALDRETE, Encinitas, CA (US)

(21) Appl. No.: 19/085,120

(22) Filed: Mar. 20, 2025

(51) Int. Cl. H01L 23/538; H01L 21/48; H01L 21/56; H01L 23/31; H01L 23/498; H01L 25/16; H10B 80/00

(52) U.S. Cl. CPC H10W 70/611; H10W 70/093; H10W 70/65; H10W 74/01; H10W 74/111; H10W 90/00; H10W 90/401; H10W 90/701; H10B 80/00

(57) ABSTRACT

A package includes a first substrate and a second substrate. The first substrate includes a first set of conductors that define first contacts for a first die. The second substrate includes a second set of conductors that define second contacts for a second die. The device also includes a first set of interconnects electrically coupled to the first substrate. The device also includes a second set of interconnects electrically coupled to the second substrate. The device also includes a third set of interconnects electrically coupled to and disposed between the first substrate and the second substrate. The device also includes an encapsulant that at least partially surrounds the first substrate, the second substrate, and the third set of interconnects.

### FIELD

Various features relate to device packages, an in particular, to substrates for device packages.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art electronic devices generally demand a small form factor, low cost, a tight power budget, and high electrical performance. Integrated device package design has evolved in an attempt to meet these various goals; however, these goals are often in conflict with one another. For example, smaller integrated device packages may be more expensive to manufacture and provide less space for routing conductive paths between dies and/or other components of the integrated device package, which can limit electrical performance. One approach to address many of these goals is to use a package-on-package (PoP) configuration; however, PoP configurations can introduce other concerns, such as heat management. Due in part to heat management concerns, designers of high-end electronic devices may prefer side-by-side configurations. However, interconnecting two high-end dies together in a side-by-side configuration on a package substrate can result in tighter package design criteria of one die being applied throughout an entirety of the package substrate, which can increase the cost and size of the package substrate. For example, core power delivery network (PDN) design for system-on-chip (SOC) dies typically can be confined to a three-layer package substrate. However, interference caused by the PDN can degrade the performance of signal paths between the SOC and a memory die. To shield these signal paths from such interference, package substrates for SOC and memory multi-die packages typically have six or more layers. Due to the increased number of layers in the package substrate, such packaged devices have a larger thickness that can increase the size and cost of electronic devices that include these multi-die packages.

### SUMMARY

Various features relate to integrated circuit devices, integrated device packages, substrates included within integrated device packages, or a combination thereof.

One example provides a package that includes a first substrate that includes a first set of conductors that define first contacts for a first die. The package also includes a second substrate that includes a second set of conductors that define second contacts for a second die. The package also includes a first set of interconnects electrically coupled to the first substrate. The package also includes a second set of interconnects electrically coupled to the second substrate. The package also includes a third set of interconnects electrically coupled to and disposed between the first substrate and the second substrate. The package also includes an encapsulant that at least partially surrounds the first substrate, the second substrate, and the third set of interconnects.

Another example provides a method of semiconductor fabrication that includes providing a first substrate and a second substrate. The first substrate includes a first set of conductors that define first contacts for a first die and the second substrate includes a second set of conductors that define second contacts for a second die. The method includes electrically coupling a third set of interconnects between the first substrate and the second substrate. A first set of interconnects are coupled to the first substrate, and a second set of interconnects are coupled to the second substrate. The method also includes applying an encapsulant to at least partially surround the first substrate, the second substrate, and the third set of interconnects.

Optional additional aspects are described in the dependent claims.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross-sectional profile view of an exemplary package for side-by-side dies and partially overlapping interconnected substrates.

FIG. 2 illustrates a cross-sectional profile view of another exemplary package for side-by-side dies and partially overlapping interconnected substrates.

FIG. 3 illustrates a cross-sectional profile view of another exemplary package for side-by-side dies and partially overlapping interconnected substrates.

FIG. 4A illustrates a first part of an exemplary sequence for fabricating an exemplary package for side-by-side dies and partially overlapping interconnected substrates.

FIG. 4B illustrates a second part of an exemplary sequence for fabricating an exemplary package for side-by-side dies and partially overlapping interconnected substrates.

FIG. 4C illustrates a third part of an exemplary sequence for fabricating an exemplary package for side-by-side dies and partially overlapping interconnected substrates.

FIG. 5A illustrates a first part of another exemplary sequence for fabricating an exemplary package for side-by-side dies and partially overlapping interconnected substrates.

FIG. 5B illustrates a second part of another exemplary sequence for fabricating an exemplary package for side-by-side dies and partially overlapping interconnected substrates.

FIG. 5C illustrates a third part of another exemplary sequence for fabricating an exemplary package for side-by-side dies and partially overlapping interconnected substrates.

FIG. 6A illustrates a first part of another exemplary sequence for fabricating an exemplary package for side-by-side dies and partially overlapping interconnected substrates.

FIG. 6B illustrates a second part of another exemplary sequence for fabricating an exemplary package for side-by-side dies and partially overlapping interconnected substrates.

FIG. 6C illustrates a third part of another exemplary sequence for fabricating an exemplary package for side-by-side dies and partially overlapping interconnected substrates.

FIG. 7A illustrates a first part of another exemplary sequence for fabricating an exemplary package for side-by-side dies and partially overlapping interconnected substrates.

FIG. 7B illustrates a second part of another exemplary sequence for fabricating an exemplary package for side-by-side dies and partially overlapping interconnected substrates.

FIG. 7C illustrates a third part of another exemplary sequence for fabricating an exemplary package for side-by-side dies and partially overlapping interconnected substrates.

FIG. 8 illustrates an exemplary flow diagram of a method of semiconductor fabrication for a package for side-by-side dies and partially overlapping interconnected substrates.

FIG. 9 illustrates various electronic devices that may integrate an exemplary described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, components and circuitry may be shown in block diagrams in order to avoid obscuring the aspects in unnecessary detail. In other instances, well-known structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

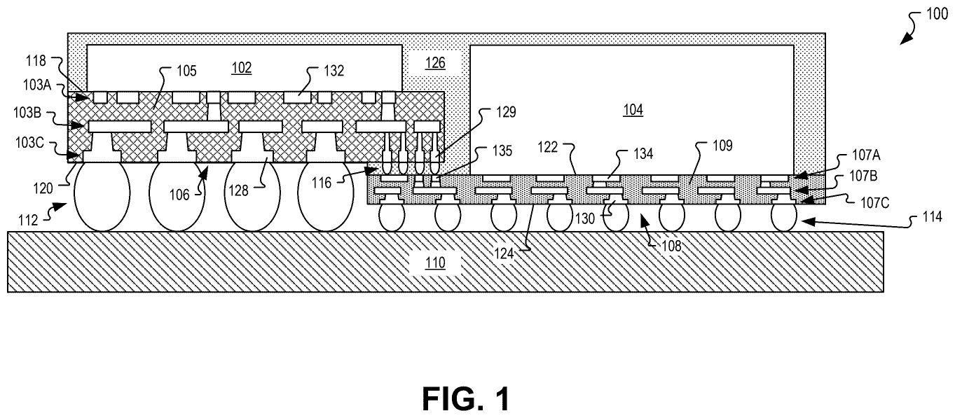

In some drawings in which multiple instances of a particular type of feature are used, different instances are distinguished by addition of a letter to the reference number. In this case, when the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1, multiple metal layers are illustrated and associated with reference numbers 103A, 103B, and 103C. When referring to a particular one of these metal layers, such as a metal layer 103A, the distinguishing letter “A” is used. However, when referring to any arbitrary one of these metal layers or to these metal layers as a group, the reference number 103 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. As used herein, a side-by-side configuration or side-by-side arrangement refers to multiple dies that are disposed adjacent to one another (typically in a horizontal direction) on the same substrate or interposer (or interconnected substrates or interposers) instead of being stacked vertically as a three-dimensional (3D) IC device. A 3D IC device refers to an IC device that stacks multiple layers of chips or chiplets on top of each other. Stacked die schemes and chiplet architectures are becoming more common as significant power performance area (PPA) yield enhancements are demonstrated for stacked die and chiplet architecture product lines.

Aspects of the present disclosure are directed to packages for side-by-side dies, for example with partially overlapping interconnected substrates. In some circumstances, side-by-side device packages may be preferred over PoP packages, such as to reduce heat management concerns. However, side-by-side device package substrates can be expensive to fabricate. For example, a typical side-by-side device package may include one or more memory dies (e.g., double data rate (DDR) dynamic random access memory (DRAM) dies) coupled to a system-on-chip (SOC) die with one or more processor cores and other circuitry. Under an exemplary set of design rules, a laminate package substrate used to provide DDR connections to a DRAM uses six metal layers in order to provide power, ground, off-package connections, and adequate isolation between signal paths. The number of metal layers needed can be reduced by using redistribution layer (RDL) materials and techniques instead of or in addition to using lamination materials and techniques; however, RDL fabrication is generally much more expensive than laminate substrate manufacturing.

Further, when multiple dies are interconnected in a side-by-side configuration, different dies may have different interconnection constraints. In this situation, if a single large package substrate is used for the entire device package, the die subject to the most demanding constraints drives the design of the package substrate, which increases cost and size of the package substrate. To illustrate, power and signal paths for a first die may be routable using only three metal layers (e.g., a first metal layer for interconnection, a second metal layer for isolation, and a third metal layer for off-package contacts); whereas routing power and signal paths for a second die may need more than three metal layers, e.g., six metal layers. In this situation, a package substrate to route connections for both of these dies would need to include six metal layers in order to accommodate the second die, leading to a larger (e.g., thicker) and more expensive package substrate.

Particular examples disclosed herein address some or all of these concerns. The examples in particular rely on using different package substrates for different dies. For example, a particular package (e.g., an integrated device package) can include a first substrate and a second substrate. In this example, the first substrate can include a first set of conductors that define first contacts for a first die, and the second substrate can include a second set of conductors that define second contacts for a second die. A first set of interconnects (e.g., interconnects configured to couple to a printed circuit board, another package, or another device or component that is not included in the package) can be electrically coupled to the first substrate, and a second set of interconnects can be coupled to the second substrate. The first and second substrates can be electrically coupled to one another by a third set of interconnects (e.g., microbumps) that are disposed between the first substrate and the second substrate (e.g., overlapping portions of the first substrate and the second substrate). The device can also include an encapsulant that at least partially surrounds the first substrate, the second substrate, and the third set of interconnects.

Using different package substrates for dies with different signal routing requirements enables the layer count of each package substrate to be limited by the corresponding die rather than the most limiting die of the package. Further, different materials and fabrication techniques can be used for different package substrates. To illustrate, in the example above, less expensive laminate materials and fabrication techniques can be used for the first substrate, and more expensive RDL materials and fabrication techniques can be used for the second substrate. Alternatively, a different set of laminate materials may be used for the second substrate. Using different package substrates, which optionally can be formed using different materials and/or different fabrication techniques, offers several technical advantages. For example, the different package substrates can each be limited by routing constraints associated with dies attached thereto, which improves design flexibility for each package substrate and can reduce overall package cost. Additionally, the individual package substrates can be redesigned or modified separately, such as due to updated constraints or use of different dies, which improves design and manufacturing flexibility. Using different package substrates for dies having different routing constraints can also enable package designers to mix more expensive and less expensive materials and fabrication techniques within a single package to address cost goals and package size goals at the same time. For example, consider a package that is to include a first die and a second die with different routing constraints (e.g., the second die's routing constraints are more limiting than the first die's routing constraints). In this example, a first package substrate for the first die may be formed using lamination techniques, and a second package substrate for the second die may be formed using RDL techniques. In this example, the first package substrate is likely to be thicker but less expensive than the second package substrate. However, the use of RDL techniques to form the second package substrate may enable the second die's routing constraints to be satisfied by a thinner package substrate than if the second package substrate were formed using lamination techniques. Thus, the overall dimensions of the package (including the first and second package substrates) are less than the overall dimensions of a package that includes a single laminate package substrate coupled to both the first and second dies. Likewise, the combined cost and/or effort of fabricating the first and second package substrates is less than the cost and/or effort of fabricating a single RDL-based package substrate coupled to both the first and second dies.

### Exemplary Packages for Side-By-Side Dies and Overlapping Interconnected Substrates

FIGS. 1-3 illustrate various examples of packages for side-by-side dies and overlapping interconnected substrates. The various examples shown in FIGS. 1-3 highlight particular non-limiting aspects of packages and substrates for packages according to the present disclosure.

In the example of FIG. 1, a package 100 (e.g., an integrated device package) includes a die 102 (e.g., a first die) that is electrically coupled to a package substrate 106 (e.g., a first package substrate) and a die 104 (e.g., a second die) that is electrically coupled to a package substrate 108 (e.g., a second package substrate). The dies 102, 104 are disposed in a side-by-side (S×S) arrangement, with the package substrates 106, 108 also side-by-side except for respective overlapping portions, as shown in FIG. 1. The package substrates 106, 108 are electrically coupled to one another by interconnects 116 (e.g., a set of interconnects) that are disposed between the package substrate 106 and the package substrate 108. The interconnects 116 electrically interconnect one or more dies (e.g., the die 102) electrically coupled to the package substrate 106 and one or more dies (e.g., the die 104) electrically coupled to the package substrate 108.

The package substrate 106 includes a set of metal layers 103 (e.g., metal layers 103A, 103B, and 103C) that are separated from one another by dielectric layers 105 and that are patterned and interconnected to form conductors (e.g., contacts, lines, and vias). The conductors of the package substrate 106 are configured according to a set of routing constraints that are associated with the die 102 (e.g., a first die) and with materials and fabrication techniques used to form the package substrate 106. For example, the metal layer 103A of the package substrate 106 defines a set of contacts 132 (e.g., a contact array) corresponding to contacts of the die 102 and included in a side 118 (e.g., a first side/a top) of the package substrate 106. Further, the metal layer 103C defines a set of off-package contacts 128 included in a side 120 (e.g., a second side/a bottom) of the package substrate 106 and configured to be coupled, via interconnects 112 (e.g., solder balls or solder bumps), to a printed circuit board (PCB) 110. In other examples, the off-package contacts 128 are configured to couple, via the interconnects 112, to another electrical interconnection and/or one or more other devices (e.g., other discrete components, other packages, etc., instead of the PCB 110). The metal layer 103C also defines a set of contacts 129 included in the side 120 of the package substrate 106 and configured to be coupled, via the interconnects 116, to contacts 135 of the package substrate 108.

In the example shown in FIG. 1, the metal layer 103B is configured to route power and ground between and among respective pairs or sets of the contacts 132 and the off-package contacts 128. For example, the metal layer 103B may support a power delivery network (PDN) associated with the die 102. Additionally, the metal layer 103B is configured to route signals between and among respective pairs or sets of the contacts 132 and the contacts 129. In some embodiments, a few signals associated with the die 102 may also be routed by the metal layer 103B between and among respective pairs or sets of the contacts 132 and the off-package contacts 128.

Similarly, the package substrate 108 includes a set of metal layers 107 (e.g., metal layers 107A, 107B, and 107C) that are separated from one another by dielectric layers 109 and that are patterned and interconnected to form conductors (e.g., contacts, lines, and vias). The conductors of the package substrate 108 are configured according to a set of routing constraints that are associated with the die 104 and with materials and fabrication techniques used to form the package substrate 108. For example, the metal layer 107A of the package substrate 108 defines a set of contacts 134 (e.g., a contact array) corresponding to contacts of the die 104 and included in a side 122 (e.g., a first side/a top) of the package substrate 108. The metal layer 107A also defines the set of contacts 135 included in the side 122 of the package substrate 108 and configured to be coupled, via the interconnects 116, to the contacts 129 of the package substrate 106. Further, the metal layer 107C defines a set of off-package contacts 130 included in a side 124 (e.g., a second side/a bottom) of the package substrate 108 and configured to be coupled, via interconnects 114, to the PCB 110. In other examples, the off-package contacts 130 are configured to couple, via the interconnects 114, to another electrical interconnection and/or one or more other devices (e.g., other discrete components, other packages, etc., instead of the PCB 110).

In the example shown in FIG. 1, the metal layer 107B is configured to route power and ground between and among respective pairs or sets of the contacts 134 and the off-package contacts 130. For example, the metal layer 107B may support a PDN associated with the die 104. Additionally, the metal layer 107B is configured to route signals between and among respective pairs or sets of the contacts 134 and the contacts 135. In some embodiments, a few signals associated with the die 104 may also be routed by the metal layer 107B between and among respective pairs or sets of the contacts 134 and the off-package contacts 130.

The package 100 of FIG. 1 includes an encapsulant 126 that at least partially encapsulates the die 102, the package substrate 106, the die 104, the package substrate 108, and the interconnects 116. The encapsulant 126 is configured to retain the package substrate 106 and the package substrate 108 in position relative to one another in a side-by-side configuration. For example, the encapsulant 126 resists warpage of the package 100 and helps to maintain the side 120 (e.g., a bottom surface) of the package substrate 106 recessed from the side 122 (e.g., a top surface) of the package substrate 108 such that the interconnects 116 are disposed between overlapping portions of the package substrates 106, 108 (e.g., a portion of the package substrate 106 that includes the contacts 129 and a portion of the package substrate 108 that includes the contacts 135), and coupled to the side 120 of the package substrate 106 and the side 122 of the package substrate 108. In some implementations, the encapsulant 126 includes or corresponds to a mold compound. Alternatively, the encapsulant 126 may be a different type of compound, such as adhesive or glue, that provides a mechanical connection between at least the package substrate 106 and the package substrate 108. In some aspects, the interconnects 116 may be coupled to the contacts 129 of the package substrate 106 and to the contacts 135 of the package substrate 108. The interconnects 116 may include microbumps, conductive pillars or micropillars, small solder balls, or other conductive material or structures that fit between the package substrates 106, 108. The interconnects 116 may be configured to route signals (e.g., via data paths) between the die 102 and the die 104 (e.g., between the contacts 129 and the contacts 135, which are subsequently routed through the metal layers 103B, 107B, respectively).

In the example illustrated in FIG. 1, a single intermediate metal layer (e.g., metal layer 103B) is disposed between a top metal layer (e.g., metal layer 103A) and a bottom metal layer (e.g., metal layer 103C) of the package substrate 106; however, in other examples, the package substrate 106 can include more than one intermediate metal layer. For example, the package substrate 106 can include as many intermediate metal layers as are needed to route signals, power, and ground between the die 102 and the off-package contacts 128 and the contacts 129 of the package substrate 106 based on the routing constraints associated with the package substrate 106. The routing constraints can depend on materials and fabrication techniques used to form the package substrate 106, characteristics of the die 102, industry or company standard design considerations, etc. To illustrate, the routing constraints may be based on line width and line spacing of conductive lines of the metal layers 103 associated with materials and fabrication techniques used to form the package substrate 106, line separation selected to maintain signal integrity for various signals routed to or from the die 102, a contact configuration of the die 102, etc.

Likewise, although the package substrate 108 is illustrated in FIG. 1 with a single intermediate metal layer (e.g., metal layer 107B) disposed between a top metal layer (e.g., metal layer 107A) and a bottom metal layer (e.g., metal layer 107C) of the package substrate 108, in other examples, the package substrate 108 can include more than one intermediate metal layer. For example, the package substrate 108 can include as many intermediate metal layers as are needed to route signals, power, and ground between the die 104 and the off-package contacts 130 and the contacts 135 of the package substrate 108 based on the routing constraints associated with the package substrate 108.

The package substrates 106, 108 can have different dimensions (e.g., different thicknesses, different widths, different shapes, etc.) than one another. For example, in FIG. 1, the package substrate 106 is shown as having a different (e.g., greater) thickness than the package substrate 108. In this example, the difference in thickness can be due to differences in the thickness or count of metal layers 103 as compared to the thickness or count of metal layers 107, differences in the thickness or count of dielectric layers 105 as compared to the thickness or count of dielectric layers 109, or both. As one illustrative example, the package substrate 106 can be formed using lamination techniques, and the package substrate 108 can be formed using redistribution layer fabrication techniques. In this illustrative example, the package substrate 106 includes a metal-prepreg composite stack, in which the dielectric layers 105 include fiber-reinforced polymer layers. In contrast, in this illustrative example, the package substrate 108 includes a set of redistribution layers, in which the dielectric layers 109 include unreinforced polymer layers. Further, as in this illustrative example, the metal layers 107 are each thinner than the metal layers 103, as is typical for redistribution layers as compared to laminated metal-prepreg composite stacks. In other examples, the package substrates 106, 108 may each include a respective metal-prepreg composite stack, and the materials associated with the package substrate 108 may be cheaper and thinner than the material associated with the package substrate 106.

Due to the different materials and/or fabrication techniques used to form the package substrates 106, 108, the package substrates 106, 108 can have different thicknesses even if the count of metal layers 103, 107 of the package substrates 106, 108 are equal to one another. For example, the package substrate 106 has a first count of the metal layers 103 (e.g., three in FIG. 1), and the package substrate 108 has a second count of the metal layers 107 (e.g., three in FIG. 1) that is equal to the first count; nevertheless, the package substrates 106, 108 have different thicknesses due to the different materials and/or fabrication techniques used to form them. The materials and fabrication techniques used to form each of the package substrates 106, 108 can also influence other characteristics of the package substrates 106, 108. For example, differences between the materials and fabrication techniques used to form redistribution layers as compared to laminated metal-prepreg stacks can enable the redistribution layers to have comparatively finer line width and finer pitch between lines and/or contacts, which enables higher density routing of signal paths. Although a layer count of the package substrate 106 is described as being the same as a layer count of the package substrate 108, in other embodiments, the layer count of the package substrate 106 may be different than the layer count of the package substrate 108, based on design criteria associated with the materials of the substrates or the respective dies.

Additionally, due to different structures and/or fabrication techniques used to form the interconnects 116 as compared to the interconnects 112, 114 and the different characteristics of the package substrates 106, 108, one or more of the interconnects 116, the interconnects 112, and the interconnects 114 can have different characteristics, such as pitch and/or size. For example, a first pitch associated with the interconnects 112 may be greater than a second pitch associated with the interconnects 114, and the second pitch may be greater than a third pitch associated with the interconnects 116. As referred to herein, a pitch associated with a set of interconnects refers to a distance between two adjacent interconnects measured from corresponding points of the two adjacent interconnects, such as the centers of the respective interconnects. As a non-limiting example, the first pitch associated with the interconnects 112 can be between approximately 0.34 and 0.375 millimeters (mm), such as 0.34 mm, 0.35 mm, or 0.375 mm, and the second pitch associated with the interconnects 114 can be between approximately 0.3 mm and 0.325 mm, such as 0.3 mm or 0.325 mm. Alternatively, the second pitch associated with the interconnects 114 may be greater than the first pitch associated with the interconnects 112, and the first pitch may be greater than the third pitch associated with the interconnects 116.

Each of the dies 102, 104 can include various circuits. For example, each of the dies 102, 104 can include integrated circuitry, such as a plurality of transistors and/or other circuit elements arranged and interconnected to form logic cells, memory cells, filters, amplifiers, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate. As non-limiting examples, the die 102, the die 104, or both, can include one or more of a power management integrated circuit (PMIC), an application processor, a modem, a radio frequency (RF) device, a passive device, a filter, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory circuit, a power management processor, and/or combinations thereof. In additional non-limiting examples, the die 102, the die 104, or both, can include one or more microcontrollers, application specific integrated circuits (ASICs), field programmable gate arrays (FPGAs), central processing units (CPUs) having one or more processing cores, processing systems, system-on-chip (SoC), or other circuitry and logic configured to facilitate the operations of the dies 102, 104. Additionally, or alternatively, one or both of the dies 102, 104 may include or be operated as a memory, such as a static random-access memory (SRAM), a DRAM, flash memory, read-only memory (ROM), programmable read-only memory (PROM), erasable programmable read-only memory (EPROM), electrically erasable programmable read-only memory (EEPROM), a solid-state storage device (SSD), or a combination thereof.

In addition to active circuits, one or both of the dies 102, 104 can include various passive components, such as capacitors, inductors, or resistors. Further, while each die 102, 104 is illustrated as a single monolithic device in FIG. 1, in other embodiments, the die 102, the die 104, or both, can include or be replaced with a stacked integrated circuit device, e.g., a stack of chiplets. For example, the die 102, the die 104, or both, may include or correspond to a three-dimensional (3D) integrated circuit (IC) device.

In one non-limiting example, the die 102 includes one or more processor cores, and the die 104 includes one or more memory cells accessible to the one or more processor cores via the interconnects 116. To illustrate, in this example, the contacts 129 of the package substrate 106 can be arranged according to a Joint Electron Device Engineering Council (JEDEC) Solid State Technology Association specification for double data rate (DDR) dynamic random access memory (DRAM) interconnection. In such an example, conductors within the package substrate 106 that are connected to protocol outputs (e.g., physical (PHY) protocol outputs) of the die 102 may be coupled to conductors in the package substrate 108 that are connected to control inputs of the die 104, thereby providing data paths by which the die 102 can perform read or write operations with respect to the die 104. As noted above, using conventional lamination techniques and materials, routing signal, power, and ground for a DDR DRAM (e.g., the die 104) in the package substrate 106 would typically require six metal layers; however, by using redistribution layer fabrication techniques to form the package substrate 108, the package substrate 108 can be formed to route signal, power, and ground paths in as few as three metal layers (e.g., due to higher density routing of signal paths, as described above). As a result, overall dimensions (e.g., thickness) of the package 100 can be reduced relative to a device package that uses a single monolithic laminate package substrate for both dies 102 and 104. Furthermore, fabrication of the package substrate 106 is considerably less expensive than would be fabrication of a single monolithic redistribution layer-based package substrate for both die 102 and 104. In some other implementations, the die 104 and the die 106 include or correspond to respective chiplets (e.g., a first chiplet and a second chiplet).

The package 100 of FIG. 1 thus provides a S×S multi-die package with reduced thickness as compared to other S×S multi-die packages. For example, by replacing a single package substrate with the S×S and overlapping package substrates 106, 108 that are electrically coupled together by the interconnects 116, the package substrates 106, 108 can be designed to support PDNs between the contacts 132 and the off-package contacts 128 and between the contacts 134 and the off-package contacts 130 while routing signals between the package substrates 106, 108 through the interconnects 116. Using a respective package substrate for each of the dies 102, 104 enables each substrate to be designed according to design rules associated with the respective die, which can reduce the number of layers in each of the package substrates 106, 108 as compared to using a single package substrate that is designed according to the rules of both dies 102, 104. Reducing the number of layers in the package substrates 106, 108 may reduce the overall thickness and cost of the package 100. Another technical advantage of the package 100 is that die-to-die signals are routed independently (e.g., through the interconnects 116) of power and ground signals, which can reduce interference with the die-to-die signals, thereby improving performance of the dies 102, 104. Additionally, because each of the dies 102, 104 is coupled to a respective one of the package substrates 106, 108, the package substrates 106, 108 may be tested with only one die attached (e.g., prior to coupling the package substrate 106 to the package substrate 108), which can decrease testing time and associated costs as compared to testing a single package substrate with multiple dies attached.

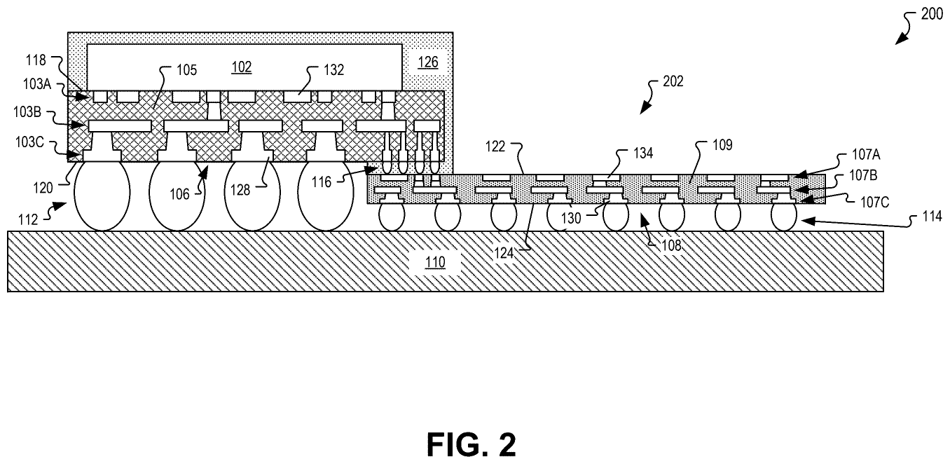

FIG. 2 illustrates an example of a package 200 that includes many of the same features as the package 100 of FIG. 1. For example, the package 200 includes the die 102 electrically coupled to the package substrate 106. The package 200 also includes the package substrate 108 and the interconnects 116 electrically coupling the package substrates 106, 108.

In the example illustrated in FIG. 2, the die 104 and a portion of the encapsulant 126 are omitted to define a region 202 configured to receive the die 104 at a later time. To illustrate, a first manufacturer may fabricate the package 200 of FIG. 2, and a second manufacturer may subsequently electrically couple the die 104 to the package 200 to form the package 100. In this illustrative example, the second manufacturer can optionally add additional encapsulant 126 to at least partially encapsulate the die 104 after it is electrically coupled to the package substrate 108.

As one non-limiting example, the contacts 134 of the package substrate 108 can be arranged according to a standard configuration, such as the JEDEC Solid State Technology Association specification for DDR DRAM interconnection. In this example, the die 104 can include a set of pins or contacts that are also arranged according to the standard configuration (e.g., the die 104 can include a JEDEC-compliant DRAM die). In this example, the first manufacture can fabricate the package 200, including components such as the die 102 and/or other components including one or more processor cores and provide the package 200 to the second manufacturer for completion with a JEDEC-compliant DRAM die selected by the second manufacturer.

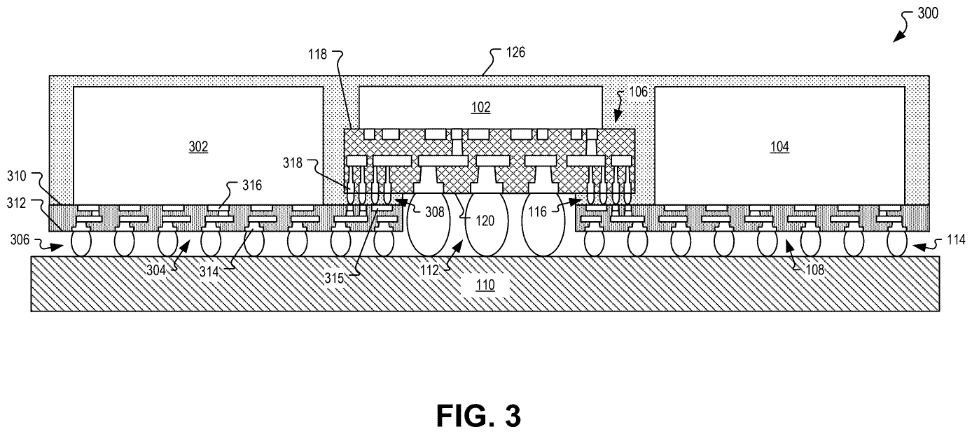

FIG. 3 illustrates an example of a package 300 that includes all of the same features as the package 100 of FIG. 1 and also includes one or more additional package substrates. For example, in FIG. 3, the package 300 includes the package substrate 106, the package substrate 108, and a package substrate 304 that is in a S×S arrangement with and partially overlaps with the package substrate 106. A die 302 is electrically coupled to the package substrate 304, such that the die 302 is in a S×S arrangement with the die 102.

The package substrate 304 has similar features to the package substrates 106, 108. For example, the package substrate 304 includes a plurality of metal layers that are separated from one another by dielectric layers and that are patterned to define conductors to route signals, power, and ground. To illustrate, the metal layers define contacts 316 (e.g., a contact array) included in a side 310 (e.g., a first side or top) of the package substrate 304 that are configured to electrically couple the die 302 to the package substrate 304. The metal layers also define or are electrically coupled to off-package contacts 314 included in side 312 (e.g., a second side or bottom) of the package substrate 304 and/or contacts 315 included in the side 310 of the package substrate 304. The off-package contacts 314 are configured to be coupled, via interconnects 306 (e.g., solder balls or solder bumps), to the PCB 110 (or another structure external to the package 300, in other embodiments). The contacts 315 are configured to be coupled to the package substrate 106 by interconnects 308 (e.g., a set of interconnects).

Similar to the interconnects 116, the interconnects 308 may be coupled to contacts 318 of the package substrate 106 and the contacts 315 of the package substrate 304. The interconnects 308 may include microbumps, conductive pillars or micropillars, small solder balls, or other conductive material or structures that fit between the package substrates 106, 304. Thus, the interconnects 116 may form portions of conductive paths (e.g., data paths) between the package substrates 106, 304 to enable routing of signals between the dies 102 and 302.

A count of metal layers of the package substrate 304 is based on routing constraints associated with the package substrate 304, as previously described. Thus, the package substrate 304 can include the same count of metal layers as either or both of the package substrates 106, 108, or the package substrate 304 can include a different count of metal layers than either of the package substrates 106, 108. Further, the package substrate 304 can be fabricated using the same materials and/or techniques as either or both of the package substrates 106, 108, or the package substrate 304 can be fabricated using different materials and/or techniques than both of the of the package substrates 106, 108. In some embodiments, the package substrate 304 includes one or more redistribution layers. Alternatively, the package substrate 304 may include one or more laminate layers having a thickness that is less than a thickness of laminate layers of the package substrate 106. Additionally, or alternatively, a pitch associated with the interconnects 308 may be similar to or the same as the pitch associated with the interconnects 116 due to the same or similar structures and/or fabrication techniques being used to form the interconnects 116, 308. In this example, the pitch associated with the interconnects 308 may be less than the pitch associated with the interconnects 306.

The encapsulant 126 of the package 300 at least partially encapsulates the package substrate 304 and the interconnects 308. Optionally, the encapsulant 126 can also at least partially encapsulate the die 302. Alternatively, the die 302 and a portion of the encapsulant 126 shown in FIG. 3 can be omitted to expose the contacts 316 for later attachment of the die 302.

Although FIG. 3 illustrates an example of the package 300 with three package substrates 106, 108, 304 interconnected by two sets of interconnects 116, 308, in other examples, the package 300 can include more than three package substrates, in which case the additional package substrates at least partially overlap with the package substrate 106 and additional interconnects (e.g., microbumps) can be used to electrically couple the additional package substrates to the package substrate 106, or to another in various other combinations. In such embodiments, the additional package substrates include additional dies (e.g., a fourth die, etc.). Further, although the three package substrates 106, 108, 304 shown in FIG. 3 are arranged in a row or line, in other embodiments, three or more package substrates can be arranged and electrically interconnected in a different geometry. For example, the three package substrates 106, 108, 304 of FIG. 3 can be arranged in a triangular configuration in which case, in addition to being electrically coupled to the package substrate 106 by the interconnects 116, 308, the package substrate 108 and the package substrate 304 may be electrically coupled to one another by one or more additional sets of interconnects (e.g., microbumps).

In a particular implementation, each of the packages 100, 200, and 300 includes a first substrate (e.g., the package substrate 106) including a first set of conductors (e.g., the metal layers 103) that define first contacts (e.g., the contacts 132) for a first die (e.g., the die 102). Each of the packages 100, 200, 300 also includes a second substrate (e.g., the package substrate 108) including a second set of conductors (e.g., the metal layers 107) that define second contacts (e.g., the contacts 134) for a second die (e.g., the die 104). Each of the packages 100, 200, and 300 also includes a first set of interconnects (e.g., the interconnects 112) electrically coupled to the first substrate. Each of the packages 100, 200, 300 also includes a second set of interconnects (e.g., the interconnects 114) electrically coupled to the second substrate. Each of the packages 100, 200, and 300 also includes a third set of interconnects (e.g., the interconnects 116) electrically coupled to and disposed between the first substrate and the second substrate. Each of the packages 100, 200, 300 also includes an encapsulant (e.g., the encapsulant 126) that at least partially surrounds the first substrate, the second substrate, and the third set of interconnects.

### Exemplary Sequence for Fabricating a Package for Side-By-Side Dies and Overlapping Interconnected Substrates

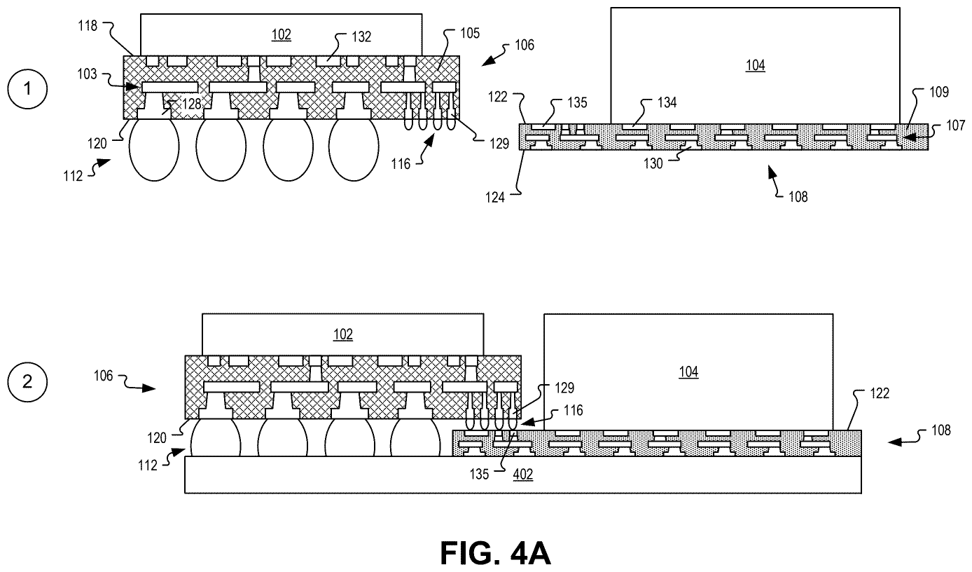

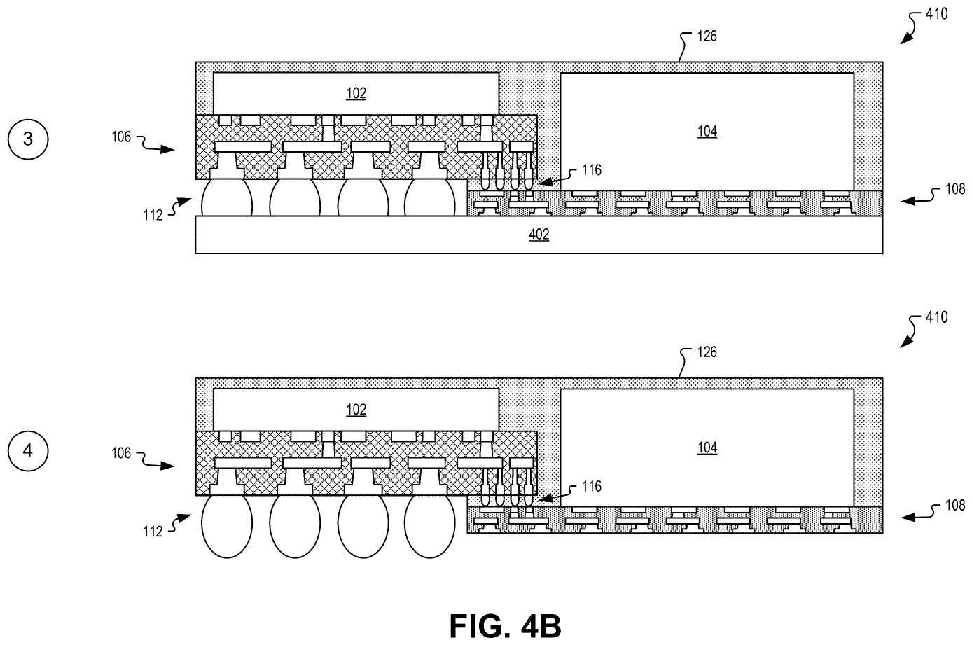

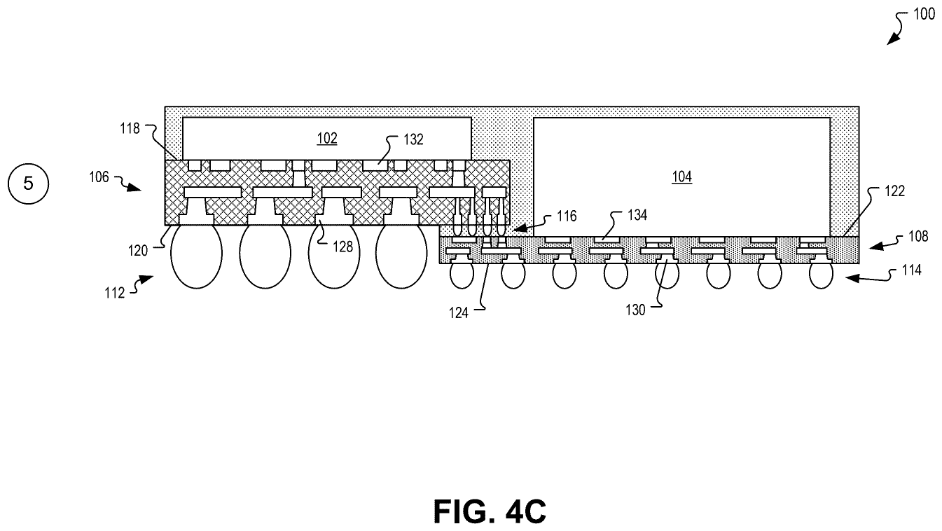

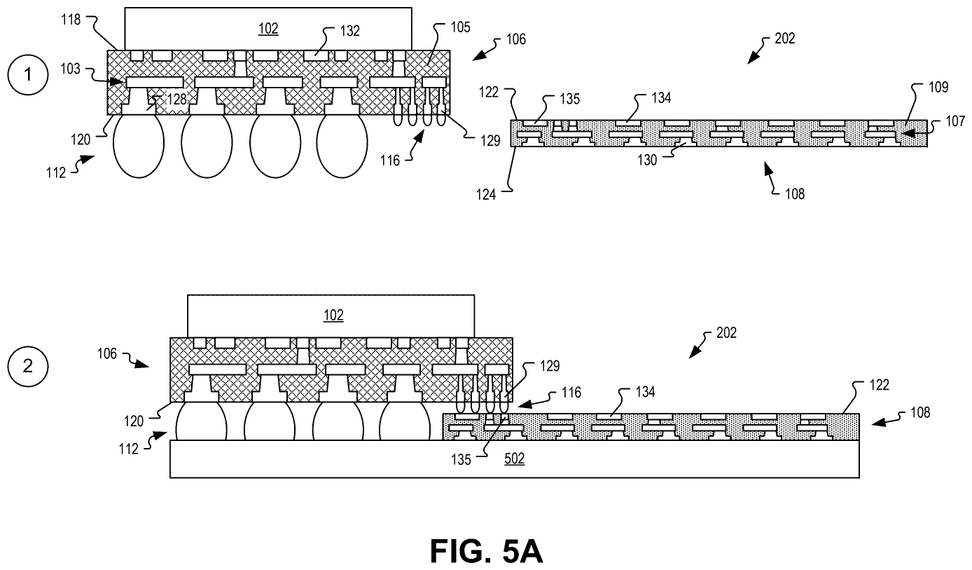

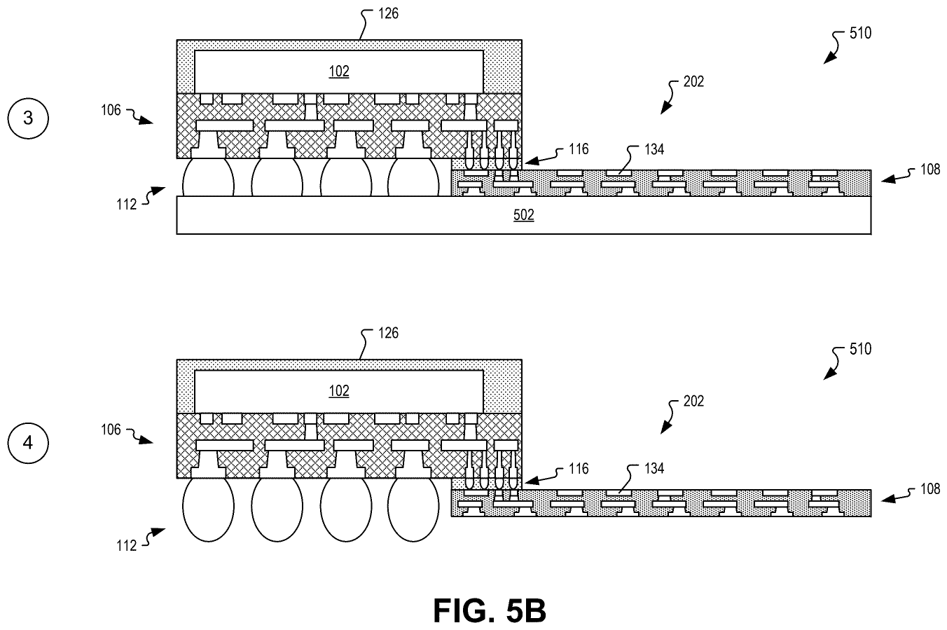

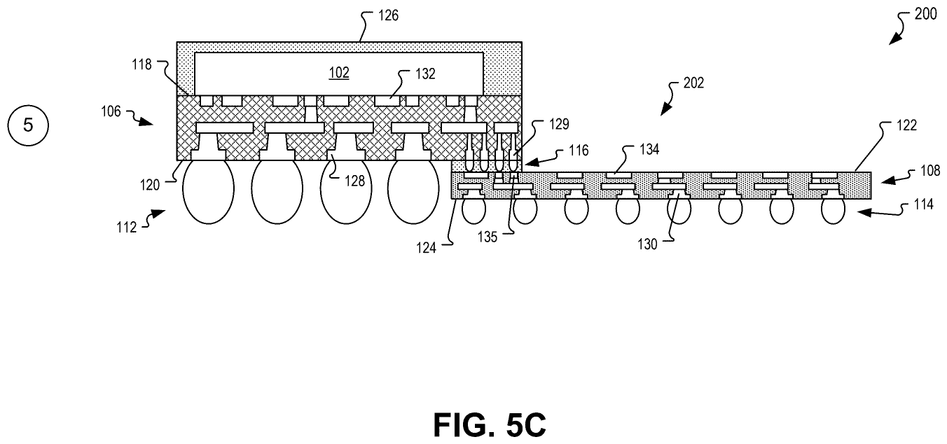

In some implementations, fabricating a package for side-by-side dies and overlapping interconnected substrates (e.g., any of the packages 100, 200, 300 of FIGS. 1-3) includes several processes. FIGS. 4A-C, 5A-C, 6A-C, and 7A-C illustrate several exemplary sequences for fabricating or providing packages for side-by-side dies and overlapping interconnected substrates, as described with reference to any of FIGS. 1-3. In some implementations, the sequences described with reference to FIGS. 4A-C or 6A-C may be used to provide (e.g., during fabrication of) one or more of the package 100 of FIG. 1 or the package 300 of FIG. 3. In some implementations, the sequences described with reference to FIGS. 5A-C or 7A-C may be used to provide (e.g., during fabrication of) the package 200 of FIG. 2.

It should be noted that the sequence of FIGS. 4A-C, 5A-C, 6A-C, and/or 7A-C may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequences. The various stages are distinguished using circled numbers in FIGS. 4A-C, 5A-C, 6A-C, and 7A-C.

In some embodiments, the various sequences represent different options for forming semiconductor devices. For example, Stages associated with FIGS. 4A-C and 6A-C are associated with fabrication of a package in which each package substrate is electrically coupled to at least one die, such as the package 100 of FIG. 1 or the package 300 of FIG. 3. In contrast, Stages associated with FIGS. 5A-C and 7A-C are associated with fabrication of a package in which contacts of at least one package substrate are left exposed for later attachment to a die, such as the package 200 of FIG. 2. Each of the various stages of the sequence illustrated in FIGS. 4A-C, 5A-C, 6A-C, and/or 7A-C shows a single integrated device being formed. In other implementations, multiple integrated devices can be formed concurrently, e.g., using strip level or panel level operations.

Stage 1 of FIG. 4A illustrates a state after formation of the package substrate 106 and the package substrate 108. For example, as part of Stage 1, the metal layers 103 and the dielectric layers 105 of the package substrate 106 are formed on a carrier (not shown), the interconnects 112 and the interconnects 116 are electrically coupled to the off-package contacts 128 and the contacts 129, respectively, and the die 102 is electrically coupled to the contacts 132. Also, as part of Stage 1, the metal layers 107 and the dielectric layers 109 of the package substrate 108 are formed on a carrier (not shown) and the die 104 is electrically coupled to the contacts 134.

In some embodiments, the package substrates 106, 108 are formed using different materials and different fabrication techniques. For example, the package substrate 106 can be formed using lamination techniques, such as arranging fiber-reinforced polymer materials (e.g., prepreg materials) and patterned metal foil layers to form laminate-based substrates. A metal foil layer can be patterned before it is applied or after it is applied to a prepreg layer. As another example, the package substrate 108 can be formed using redistribution layer fabrication techniques, such as depositing unreinforced polymer materials to form one of the dielectric layers and depositing a metal layer on the dielectric layer. In this example, the unreinforced polymer materials can be deposited as a dry film or as a liquid or gel, and the metal layers can be deposited using plating, spraying, vapor deposition, or other similar techniques used to form thin metal layers.

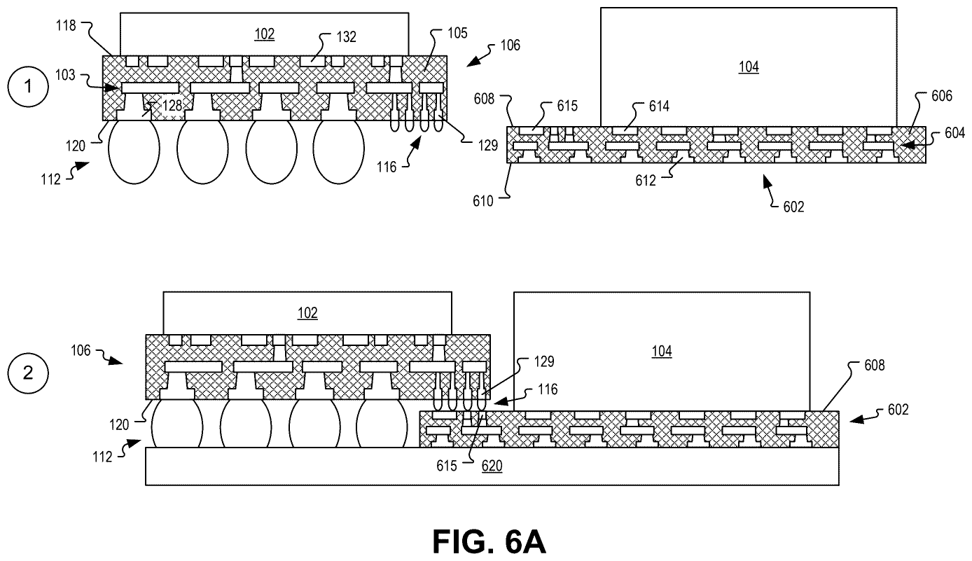

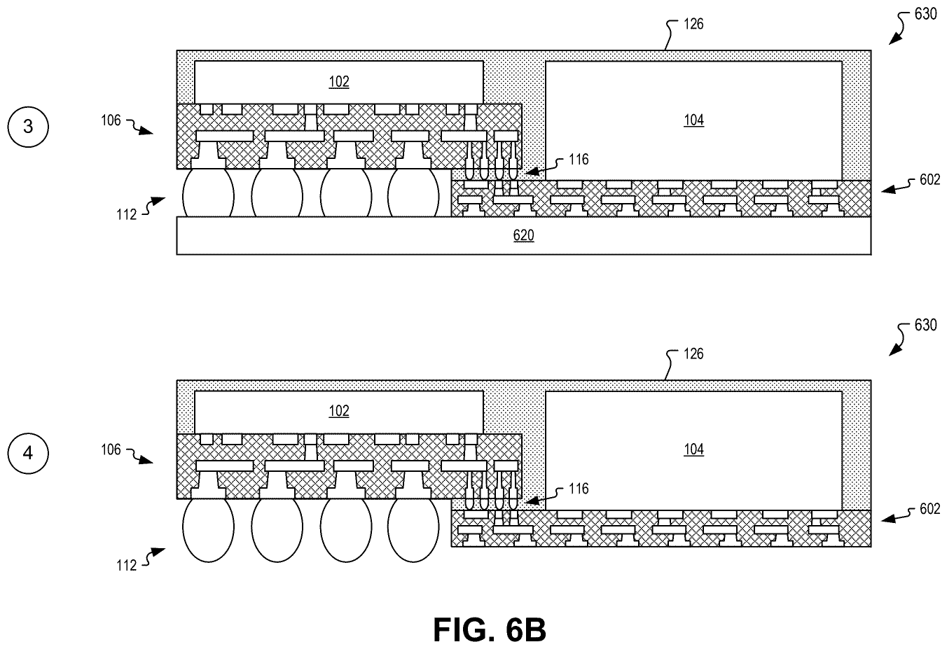

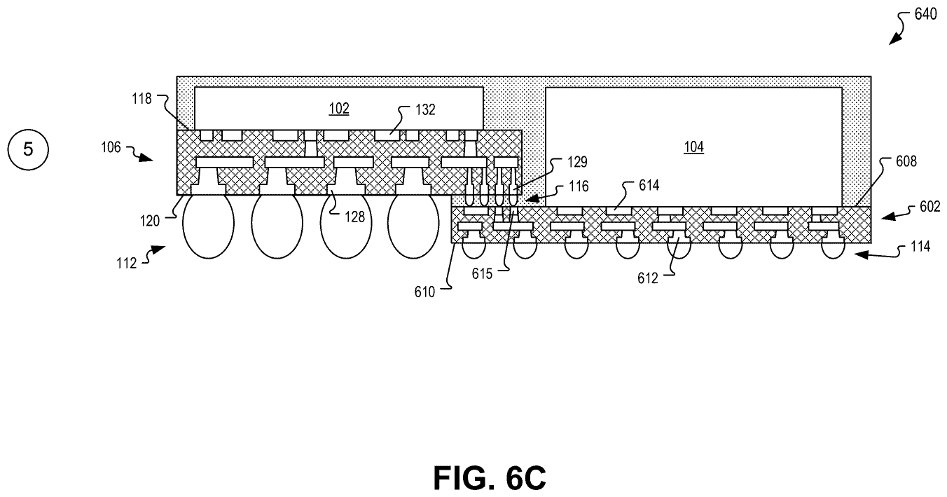

Although the example shown in FIG. 4A depicts the package substrate 106 being formed using lamination techniques and the package substrate 108 being formed using redistribution layer techniques, in other embodiments, the package substrate 106 may be formed using redistribution layer fabrication techniques and the package substrate 108 may be formed using lamination techniques. Alternatively, the package substrates 106, 108 can be formed using the same (or similar) materials and fabrication techniques, such as both substrates being formed using lamination techniques (e.g., as described further herein with reference to FIGS. 6A-C or 7A-C) or redistribution layer techniques.

The package substrates 106, 108 can have the same count of metal layers 103, 107, or different counts of metal layers 103, 107. The package substrates 106, 108 may also have the same or different layer thicknesses and/or total thicknesses. For example, the package substrate 106 may include three laminate layers and have a thickness of approximately 130 micrometers (μm), and the package substrate 108 may include three redistribution layers and have a thickness of approximately 40 μm. Further, the package substrates 106, 108 can be formed concurrently or separately. In some embodiments, the package substrate 106 can be formed at a different location than the package substrate 108, such as by a different manufacturer or at a different manufacturing facility. For example, redistribution layer fabrication techniques and laminate fabrication techniques use different tools sets and different manufacturing environments. Thus, if the package substrate 106 is formed using laminate fabrication techniques and the package substrate 108 is formed using redistribution layer fabrication techniques, the package substrates 106, 108 can be formed at different facilities or in different manufacturing lines.

The dies 102, 104 may be attached (e.g., electrically coupled) to the package substrates 106, 108 and undergo testing as part of Stage 1. To illustrate, the die 102 is coupled to the package substrate 106 using flip-chip die attach techniques, such as solder reflow or thermo-compression bonding. After the die 102 is coupled to the package substrate 106, the package substrate 106 may be tested to determine if the die 102 is properly coupled to the package substrate 106 and/or to perform other testing. Similarly, after the die 104 is coupled to the package substrate 108, such as using surface mount technology (SMT) attachment techniques, the package substrate 108 may be tested to determine if the die 104 is properly coupled to the package substrate 108 and/or to perform other testing. In some implementations, underfill may be applied to the package substrate 106 under the die 102 (e.g., before or after the testing). Additionally, the interconnects (e.g., ball grid array (BGA) balls) may be electrically coupled to the off-package contacts 128 included in the side 120 of the package substrate 106 (e.g., before or after testing). In some implementations, the interconnects 116 (e.g., microbumps) are coupled to the contacts 129 included in the side 120 of the package substrate 106. Alternatively, the interconnects 116 may be coupled to the package substrate 106 during the next stage.

Stage 2 illustrates a state after electrically coupling the interconnects 116 between the package substrate 106 and the package substrate 108. For example, as part of Stage 2, the package substrate 108 and the interconnects 112 may be coupled to a carrier 402. In some embodiments, an adhesive layer (not shown) is disposed between the package substrate 108 and the carrier 402 (and between the interconnects 112 and the carrier 402) that is configured to attach the package substrate 108 to the carrier 402 and to absorb some of the force from the interconnects 112 if force is used to couple the interconnects to the package substrate 108. The carrier 402 (or the optional adhesive layer) may be recessed to receive at least portions of the interconnects 112, as depicted in FIG. 4A. After the package substrate 108 is coupled to the carrier 402, the interconnects 116 may be coupled to the contacts 135 included in the side 122 of the package substrate 108. For example, solder reflow bonding or another type of bonding technique may be used to electrically couple the interconnects 116 to the contacts 135. The interconnects 112 may be coupled to the carrier 402 before, during, or after the interconnects 116 are coupled to the package substrate 108.

Stage 3 of FIG. 4B illustrates a state after application of the encapsulant 126 to form an assembly 410 coupled to the carrier 402. The encapsulant 126 at least partially encapsulates (e.g., surrounds) the package substrate 106, the package substrate 108 (or a portion thereof, as shown in FIG. 2), the interconnects 116, and the dies 102, 104. In a particular example, overmolding operations are used to apply the encapsulant 126 to form the assembly 410. Additionally, or alternatively, it is possible to use a compound (e.g., adhesive, glue, etc.) for mechanically coupling the package substrate 106 and the package substrate 108. Stage 4 illustrates a state after the assembly 410 is detached from the carrier 402.

Stage 5 of FIG. 4C illustrates a state after the interconnects 114 are coupled to the off-package contacts 130 of the package substrate 108 to form the package 100. For example, as part of Stage 5, small solder balls or small BGA elements (e.g., the interconnects 114) may be electrically coupled to the off-package contacts 130 included in the side 124 of the package substrate 108. Formation of the package 100 is complete after Stage 5 of FIG. 4C. In some other embodiments, the interconnects 114 may be electrically coupled to the package substrate 108 during Stage 1 (e.g., prior to electrically coupling the interconnects 116 to the package substrate 108).

In examples in which the operations described with reference to Stages 1-5 are used to fabricate a package that includes more than two package substrates (e.g., the package 300 of FIG. 3), appropriate ones of Stages 1-5 are repeated or replicated concurrently for the additional package substrates. For example, during fabrication of the package 300 of FIG. 3, three package substrates (e.g., the package substrates 106, 108, and 304) are formed at Stage 1 and are attached to the carrier 402 at Stage 2. Further, in this example, the interconnects 308 of FIG. 3 can be formed at Stage 1 of FIG. 4A and coupled to the contacts 318 using similar techniques described there.

Stage 1 of FIG. 5A illustrates a state after formation of the package substrate 106 and the package substrate 108. For example, as part of Stage 1, the metal layers 103 and the dielectric layers 105 of the package substrate 106 are formed on a carrier (not shown), the interconnects 112 and the interconnects 116 are electrically coupled to the off-package contacts 128 and the contacts 129, respectively, and the die 102 is electrically coupled to the contacts 132. Also as part of Stage 1, the metal layers 107 and the dielectric layers 109 of the package substrate 108 are formed on a carrier (not shown). The region 202 is configured to receive the die 104 at a later time.

In some embodiments, the package substrates 106, 108 are formed using different materials and different fabrication techniques. For example, the package substrate 106 can be formed using lamination techniques, such as arranging fiber-reinforced polymer materials (e.g., prepreg materials) and patterned metal foil layers to form laminate-based substrates. A metal foil layer can be patterned before it is applied or after it is applied to a prepreg layer. As another example, the package substrate 108 can be formed using redistribution layer fabrication techniques, such as depositing unreinforced polymer materials to form one of the dielectric layers and depositing a metal layer on the dielectric layer. In this example, the unreinforced polymer materials can be deposited as a dry film or as a liquid or gel, and the metal layers can be deposited using plating, spraying, vapor deposition, or other similar techniques used to form thin metal layers.

Although the example shown in FIG. 5A depicts the package substrate 106 being formed using lamination techniques and the package substrate 108 being formed using redistribution layer techniques, in other embodiments, the package substrate 106 may be formed using redistribution layer fabrication techniques and the package substrate 108 may be formed using lamination techniques. Alternatively, the package substrates 106, 108 can be formed using the same (or similar) materials and fabrication techniques, such as both substrates being formed using lamination techniques (e.g., as described further herein with reference to FIGS. 6A-C or 7A-C) or redistribution layer techniques.

The package substrates 106, 108 can have the same count of metal layers 103, 107, or different counts of metal layers 103, 107. The package substrates 106, 108 may also have the same or different layer thicknesses and/or total thicknesses. For example, the package substrate 106 may include three laminate layers and have a thickness of approximately 130 μm, and the package substrate 108 may include three redistribution layers and have a thickness of approximately 40 μm. Further, the package substrates 106, 108 can be formed concurrently or separately. In some embodiments, the package substrate 106 can be formed at a different location than the package substrate 108, such as by a different manufacturer or at a different manufacturing facility. For example, redistribution layer fabrication techniques and laminate fabrication techniques use different tools sets and different manufacturing environments. Thus, if the package substrate 106 is formed using laminate fabrication techniques and the package substrate 108 is formed using redistribution layer fabrication techniques, the package substrates 106, 108 can be formed at different facilities or in different manufacturing lines. This in particular allows for reducing the overall complexity of the integrated device, saving material and/or manufacturing steps.

The die 102 may be attached (e.g., electrically coupled) to the package substrate 106 and undergo testing as part of Stage 1. To illustrate, the die 102 is coupled to the package substrate 106 using flip-chip die attach techniques, such as solder reflow or thermo-compression bonding. After the die 102 is coupled to the package substrate 106, the package substrate 106 may be tested to determine if the die 102 is properly coupled to the package substrate 106 and/or to perform other testing. In some implementations, underfill may be applied to the package substrate 106 under the die 102 (e.g., before or after the testing). Additionally, the interconnects (e.g., BGA balls) may be electrically coupled to the off-package contacts 128 included in the side 120 of the package substrate 106 (e.g., before or after testing). In some implementations, the interconnects 116 (e.g., microbumps) are coupled to the contacts 129 included in the side 120 of the package substrate 106. Alternatively, the interconnects 116 may be coupled to the package substrate 106 during the next stage.

Stage 2 illustrates a state after electrically coupling the interconnects 116 between the package substrate 106 and the package substrate 108. For example, as part of Stage 2, the package substrate 108 and the interconnects 112 may be coupled to a carrier 502. In some embodiments, an adhesive layer (not shown) is disposed between the package substrate 108 and the carrier 502 (and between the interconnects 112 and the carrier 402) that is configured to attach the package substrate 108 to the carrier 502 and to absorb some of the force from the interconnects 112 if force is used to couple the interconnects to the package substrate 108. The carrier 502 (or the optional adhesive layer) may be recessed to receive at least portions of the interconnects 112, as depicted in FIG. 5A. After the package substrate 108 is coupled to the carrier 502, the interconnects 116 may be coupled to the contacts 135 included in the side 122 of the package substrate 108. For example, solder reflow bonding or another type of bonding technique may be used to electrically couple the interconnects 116 to the contacts 135. The interconnects 112 may be coupled to the carrier 502 before, during, or after the interconnects 116 are coupled to the package substrate 108.

Stage 3 of FIG. 5B illustrates a state after application of the encapsulant 126 to form an assembly 510 coupled to the carrier 502. The encapsulant 126 is selectively applied such that the contacts 134 of the package substrate 108 are not covered by the encapsulant 126. For example, the encapsulant 126 at least partially encapsulates the package substrates 106, 108, the interconnects 116, and the die 102 and leaves the contacts 134 exposed in the region 202. In a particular example, overmolding operations are used to apply the encapsulant 126 to form the assembly 510. Stage 4 illustrates a state after the assembly 510 is detached from the carrier 502.

Stage 5 of FIG. 5C illustrates a state after the interconnects 114 are coupled to the off-package contacts 130 of the package substrate 108 to form the package 100. For example, as part of Stage 5, small solder balls or small BGA elements (e.g., the interconnects 114) may be electrically coupled to the off-package contacts 130 included in the side 124 of the package substrate 108. Formation of the package 200 is complete after Stage 5 of FIG. 5C, however, additional operations may subsequently be performed to attach a die to exposed contacts 134 within the region 202. For example, die attach operations, such as solder reflow or thermo-compression bonding, can be used to attach a die to the contacts 134 in the region 202, and optionally, overmolding operations can be used to add additional encapsulant to at least partially surround the die attached in the region 202. In some other embodiments, the interconnects 114 may be electrically coupled to the package substrate 108 during Stage 1 (e.g., prior to electrically coupling the interconnects 116 to the package substrate 108).

In examples in which the operations described with reference to Stages 1-5 are used to fabricate a package that includes more than two package substrates, appropriate ones of Stages 1-5 are repeated or replicated concurrently for the additional package substrates. For example, during fabrication of such a package, three package substrates (e.g., the package substrates 106, 108, and 304) are formed at Stage 1 and are attached to the carrier 502 at Stage 2, with at least one region 202 left for attachment of additional die(s). Further, in this example, the interconnects 308 of FIG. 3 can be formed at Stage 1 of FIG. 5A and coupled to the contacts 318 using similar techniques described there.

Stage 1 of FIG. 6A illustrates a state after formation of the package substrate 106 and a package substrate 602. The package substrate 602 may be similar to the package substrate 108 except for being formed from different materials and/or using different formation techniques. For example, as part of Stage 1, the metal layers 103 and the dielectric layers 105 of the package substrate 106 are formed on a carrier (not shown), the interconnects 112 and the interconnects 116 are electrically coupled to the off-package contacts 128 and the contacts 129, respectively, and the die 102 is electrically coupled to the contacts 132. Also as part of Stage 1, metal layers 604 and dielectric layers 606 of the package substrate 602 are formed on a carrier (not shown). The metal layers 604 may form contacts 614 and contacts 615 included in a side 608 (e.g., a first or top) of the package substrate 602, and the metal layers 604 may form contacts 612 included in a side 610 (e.g., a second side or bottom) of the package substrate 602. The die 104 is electrically coupled to the contacts 614.

In some embodiments, the package substrates 106, 602 are formed using the same or similar materials and/or the same or similar fabrication techniques. For example, each of the package substrates 106, 602 can be formed using lamination techniques, such as arranging fiber-reinforced polymer materials (e.g., prepreg materials) and patterned metal foil layers to form laminate-based substrates. A metal foil layer can be patterned before it is applied or after it is applied to a prepreg layer. Although the example shown in FIG. 6A depicts the package substrate 106 being formed using lamination techniques and the package substrate 602 being formed using lamination techniques, in other embodiments, the package substrate 106 and the package substrate 602 may be formed using redistribution layer fabrication techniques. Alternatively, the package substrates 106, 108 can be formed using different materials and different fabrication techniques (e.g., as described further herein with reference to FIGS. 4A-C or 5A-C).

The package substrates 106, 602 can have the same count of metal layers 103, 604, or different counts of metal layers 103, 604. The package substrates 106, 602 may also have the same or different layer thicknesses and/or total thicknesses. For example, the package substrate 106 may include three laminate layers and have a thickness of approximately 130 μm, and the package substrate 602 may include three laminate layers formed from a different quality of material and having a thickness of approximately 90 μm. Further, the package substrates 106, 602 can be formed concurrently or separately. In some embodiments, the package substrate 106 can be formed at a different location than the package substrate 602, such as by a different manufacturer or at a different manufacturing facility. Alternatively, the package substrates 106, 602 can be formed at the same facilities or in the same manufacturing lines.

The dies 102, 104 may be attached (e.g., electrically coupled) to the package substrates 106, 602 and undergo testing as part of Stage 1. To illustrate, the die 102 is coupled to the package substrate 106 using flip-chip die attach techniques, such as solder reflow or thermo-compression bonding. After the die 102 is coupled to the package substrate 106, the package substrate 106 may be tested to determine if the die 102 is properly coupled to the package substrate 106 and/or to perform other testing. Similarly, after the die 104 is coupled to the package substrate 602, such as using flip-chip die attach techniques, such as solder reflow or thermo-compression bonding, the package substrate 602 may be tested to determine if the die 104 is properly coupled to the package substrate 602 and/or to perform other testing. In some implementations, underfill may be applied to the package substrate 106 under the die 102 (e.g., before or after the testing). Additionally, the interconnects (e.g., BGA balls) may be electrically coupled to the off-package contacts 128 included in the side 120 of the package substrate 106 (e.g., before or after testing). In some implementations, the interconnects 116 (e.g., microbumps) are coupled to the contacts 129 included in the side 120 of the package substrate 106. Alternatively, the interconnects 116 may be coupled to the package substrate 106 during the next stage.

Stage 2 illustrates a state after electrically coupling the interconnects 116 between the package substrate 106 and the package substrate 602. For example, as part of Stage 2, the package substrate 602 and the interconnects 112 may be coupled to a carrier 620. In some embodiments, an adhesive layer (not shown) is disposed between the package substrate 602 and the carrier 620 (and between the interconnects 112 and the carrier 620) that is configured to attach the package substrate 602 to the carrier 620 and to absorb some of the force from the interconnects 112 if force is used to couple the interconnects to the package substrate 602. The carrier 620 (or the optional adhesive layer) may be recessed to receive at least portions of the interconnects 112, as depicted in FIG. 6A. After the package substrate 602 is coupled to the carrier 620, the interconnects 116 may be coupled to the contacts 615 included in the side 608 of the package substrate 602. For example, solder reflow bonding or another type of bonding technique may be used to electrically couple the interconnects 116 to the contacts 615. The interconnects 112 may be coupled to the carrier 620 before, during, or after the interconnects 116 are coupled to the package substrate 602.

Stage 3 of FIG. 6B illustrates a state after application of the encapsulant 126 to form an assembly 630 coupled to the carrier 620. The encapsulant 126 at least partially encapsulates the package substrates 106, 602, the interconnects 116, and the dies 102, 104. In a particular example, overmolding operations are used to apply the encapsulant 126 to form the assembly 630. Stage 4 illustrates a state after the assembly 630 is detached from the carrier 620.

Stage 5 of FIG. 6C illustrates a state after the interconnects 114 are coupled to the contacts 612 of the package substrate 602 to form a package 640. For example, as part of Stage 5, small solder balls or small BGA elements (e.g., the interconnects 114) may be electrically coupled to the contacts 612 included in the side 610 of the package substrate 602. Formation of the package 640 is complete after Stage 5 of FIG. 6C. In some other embodiments, the interconnects 114 may be electrically coupled to the package substrate 602 during Stage 1 (e.g., prior to electrically coupling the interconnects 116 to the package substrate 602).

In examples in which the operations described with reference to Stages 1-5 are used to fabricate a package that includes more than two package substrates, appropriate ones of Stages 1-5 are repeated or replicated concurrently for the additional package substrates. For example, during fabrication of such a package, three package substrates (e.g., the package substrates 106, 602, and either the package substrate 304 or a similar package substrate) are formed at Stage 1 and are attached to the carrier 620 at Stage 2. Further, in this example, the interconnects 308 of FIG. 3 can be formed at Stage 1 of FIG. 4A and coupled to the contacts 318 using similar techniques described there.

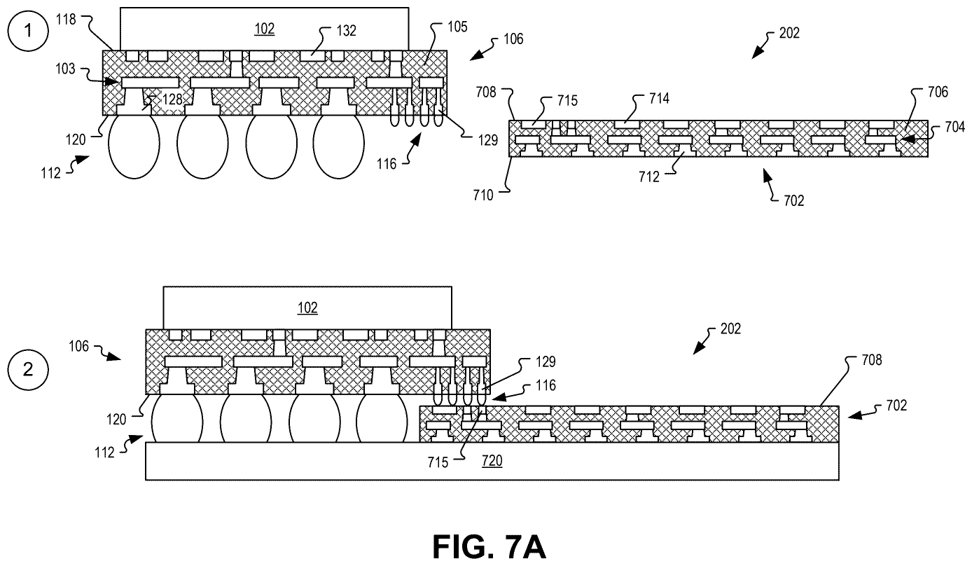

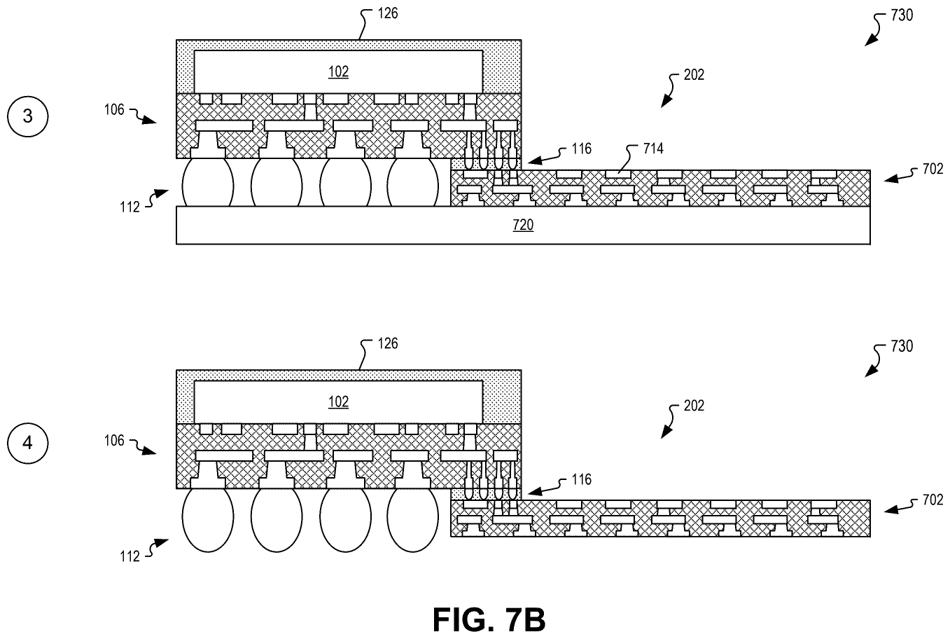

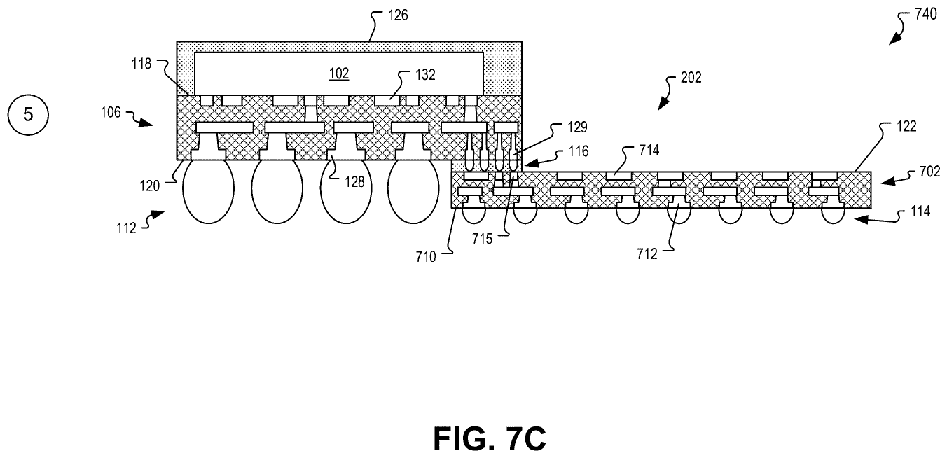

Stage 1 of FIG. 7A illustrates a state after formation of the package substrate 106 and a package substrate 702. For example, as part of Stage 1, the metal layers 103 and the dielectric layers 105 of the package substrate 106 are formed on a carrier (not shown), the interconnects 112 and the interconnects 116 are electrically coupled to the off-package contacts 128 and the contacts 129, respectively, and the die 102 is electrically coupled to the contacts 132. Also as part of Stage 1, metal layers 704 and the dielectric layers 706 of the package substrate 702 are formed on a carrier (not shown). The metal layers 704 may form contacts 714 and contacts 715 included in a side 708 (e.g., a first side or top) of the package substrate 702, and the metal layers 704 may form contacts 712 included in a side 710 (e.g., a second side or bottom) of the package substrate 702. The region 202 is configured to receive the die 104 at a later time.

In some embodiments, the package substrates 106, 702 are formed using the same or similar materials and the same or similar fabrication techniques. For example, the package substrate 106 can be formed using lamination techniques, such as arranging fiber-reinforced polymer materials (e.g., prepreg materials) and patterned metal foil layers to form laminate-based substrates. A metal foil layer can be patterned before it is applied or after it is applied to a prepreg layer. As another example, the package substrate 702 can also be formed using lamination techniques.

Although the example shown in FIG. 7A depicts the package substrates 106, 702 being formed using lamination techniques, in other embodiments, the package substrates 106, 702 may be formed using redistribution layer fabrication techniques. Alternatively, the package substrates 106, 702 can be formed using different materials and different fabrication techniques (e.g., as described further herein with reference to FIGS. 4A-C or 5A-C).

The package substrates 106, 702 can have the same count of metal layers 103, 704, or different counts of metal layers 103, 704. The package substrates 106, 702 may also have the same or different layer thicknesses and/or total thicknesses. For example, the package substrate 106 may include three laminate layers and have a thickness of approximately 130 μm, and the package substrate 702 may include three redistribution layers and have a thickness of approximately 90 μm. Further, the package substrates 106, 702 can be formed concurrently or separately. In some embodiments, the package substrate 106 can be formed at a different location than the package substrate 702, such as by a different manufacturer or at a different manufacturing facility. Alternatively, the package substrates 106, 702 can be formed at the same facilities or in the same manufacturing lines.

The die 102 may be attached (e.g., electrically coupled) to the package substrate 106 and undergo testing as part of Stage 1. To illustrate, the die 102 is coupled to the package substrate 106 using flip-chip die attach techniques, such as solder reflow or thermo-compression bonding. After the die 102 is coupled to the package substrate 106, the package substrate 106 may be tested to determine if the die 102 is properly coupled to the package substrate 106 and/or to perform other testing. In some implementations, underfill may be applied to the package substrate 106 under the die 102 (e.g., before or after the testing). Additionally, the interconnects (e.g., BGA balls) may be electrically coupled to the off-package contacts 128 included in the side 120 of the package substrate 106 (e.g., before or after testing). In some implementations, the interconnects 116 (e.g., microbumps) are coupled to the contacts 129 included in the side 120 of the package substrate 106. Alternatively, the interconnects 116 may be coupled to the package substrate 106 during the next stage.

Stage 2 illustrates a state after electrically coupling the interconnects 116 between the package substrate 106 and the package substrate 702. For example, as part of Stage 2, the package substrate 702 and the interconnects 112 may be coupled to a carrier 720. In some embodiments, an adhesive layer (not shown) is disposed between the package substrate 702 and the carrier 720 (and between the interconnects 112 and the carrier 720) that is configured to attach the package substrate 702 to the carrier 720 and to absorb some of the force from the interconnects 112 if force is used to couple the interconnects to the package substrate 702. The carrier 720 (or the optional adhesive layer) may be recessed to receive at least portions of the interconnects 112, as depicted in FIG. 7A. After the package substrate 702 is coupled to the carrier 720, the interconnects 116 may be coupled to the contacts 715 included in the side 708 of the package substrate 702. For example, solder reflow bonding or another type of bonding technique may be used to electrically couple the interconnects 116 to the contacts 715. The interconnects 112 may be coupled to the carrier 720 before, during, or after the interconnects 116 are coupled to the package substrate 702.

Stage 3 of FIG. 7B illustrates a state after application of the encapsulant 126 to form an assembly 730 coupled to the carrier 720. The encapsulant 126 is selectively applied such that the contacts 714 of the package substrate 702 are not covered by the encapsulant 126. For example, the encapsulant 126 at least partially encapsulates the package substrates 106, 702, the interconnects 116, and the die 102 and leaves the contacts 714 exposed in the region 202. In a particular example, overmolding operations are used to apply the encapsulant 126 to form the assembly 730. Stage 4 illustrates a state after the assembly 730 is detached from the carrier 720.

Stage 5 of FIG. 7C illustrates a state after the interconnects 114 are coupled to the contacts 712 of the package substrate 702 to form a package 740. For example, as part of Stage 5, small solder balls or small BGA elements (e.g., the interconnects 114) may be electrically coupled to the contacts 712 included in the side 710 of the package substrate 702. Formation of the package 740 is complete after Stage 5 of FIG. 7C, however, additional operations may subsequently be performed to attach a die to exposed contacts 714 within the region 202. For example, die attach operations, such as solder reflow or thermo-compression bonding, can be used to attach a die to the contacts 714 in the region 202, and optionally, overmolding operations can be used to add additional encapsulant to at least partially surround the die attached in the region 202. In some other embodiments, the interconnects 114 may be electrically coupled to the package substrate 702 during Stage 1 (e.g., prior to electrically coupling the interconnects 116 to the package substrate 702).

In examples in which the operations described with reference to Stages 1-5 are used to fabricate a package that includes more than two package substrates, appropriate ones of Stages 1-5 are repeated or replicated concurrently for the additional package substrates. For example, during fabrication of such a package, three package substrates (e.g., the package substrates 106, 702, and the package substrate 304 or another package substrate formed from other materials or fabrication techniques) are formed at Stage 1 and are attached to the carrier 720 at Stage 2, with at least one region 202 left for attachment of additional die(s). Further, in this example, the interconnects 308 of FIG. 3 can be formed at Stage 1 of FIG. 7A and coupled to the contacts 318 using similar techniques described there.

### Exemplary Flow Diagram of a Method for Fabricating a Package with Side-By-Side Dies and Overlapping Interconnected Substrates

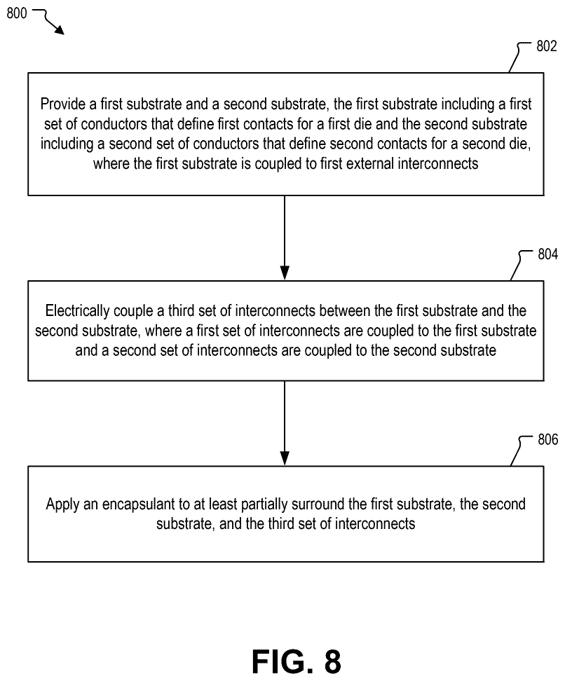

In some implementations, fabricating a package with side-by-side dies and overlapping interconnected substrates includes several processes. FIG. 8 illustrates an exemplary flow diagram of a method 800 of fabricating an illustrative package with side-by-side dies and overlapping interconnected substrates. In a particular aspect, one or more operations of the method 800 are performed by one or more processors of a fabrication system. In some implementations, operations of the method 800 may be stored as instructions by a non-transitory computer-readable storage medium, and the instructions may be executable by at least one processor to cause the at least one processor to perform operations of the method 800. In some implementations, the method 800 of FIG. 8 may be used to provide or fabricate any of the packages 100, 200, 300, 640, or 740.

It should be noted that the method 800 of FIG. 8 may combine one or more processes in order to simplify and/or clarify the method for providing or fabricating an integrated circuit device. In some implementations, the order of the processes may be changed or modified.

The method 800 includes providing a first substrate and a second substrate, at block 802. The first substrate includes a first set of conductors that define first contacts for a first die and the second substrate includes a second set of conductors that define second contacts for a second die. For example, Stage 1 of FIGS. 4A, 5A, 6A, and 7A illustrate and describe examples of forming and providing the package substrates 106, 108, 602, and 702. The first substrate of the method 800 can include or correspond to the package substrate 106 of FIGS. 1-7C. The second substrate of the method 800 can include the package substrate 108 of FIGS. 1-5C, the package substrate 602 of FIGS. 6A-C, or the package substrate 702 of FIGS. 7A-7C. In some embodiments, a first side of the first substrate includes the first contacts and a first side of the second substrate includes the second contacts. For example, the first side of the first substrate can include or correspond to the side 118 of FIGS. 1-7C, and the first side of the second substrate can include or correspond to the side 122 of FIGS. 1-5C, the side 608 of FIGS. 6A-C, or the side 708 of FIGS. 7A-C.

The method 800 includes electrically coupling a third set of interconnects between the first substrate and the second substrate, at block 804. For example, Stage 2 of FIGS. 4A, 5A, 6A, and 7A illustrate and describe examples of coupling the interconnects 116 between the package substrates 106, 108 (or 602 or 702). The set of interconnects of the method 800 can include or correspond to the interconnects 116 of FIGS. 1-7C. In this example, a first set of interconnects are coupled to the first substrate and a second set of interconnects are coupled to the second substrate. For example, the first set of interconnects can include or correspond to the interconnects 112 of FIGS. 1-7C, and the second set of interconnects can include or correspond to the interconnects 114 of FIGS. 1-3, 4C, 5C, 6C, and 7C.

The method 800 includes applying an encapsulant to at least partially surround the first substrate, the second substrate, and the third set of interconnects, at block 806. For example, Stage 3 of FIGS. 4B and 5B illustrate and describe examples of applying the encapsulant 126, and Stage 3 of FIGS. 6B and 7B illustrate and describe examples of selectively applying the encapsulant 126. The encapsulant of the method 800 can include the encapsulant 126 of FIGS. 1-7C, which at least partially encapsulates the package substrate 106, the interconnects 116, and a portion of the package substrate 108 (or either of the package substrates 602, 702). In some examples, the encapsulant includes or corresponds to a mold compound. Alternatively, the first substrate may be mechanically coupled to the second substrate, using a different compound (e.g., adhesive or a different type of encapsulant than a mold compound).

In some embodiments, the method 800 also includes, before said applying the encapsulant, electrically coupling the first die to the first contacts of the first substrate. For example, Stage 1 of FIGS. 4A, 5A, 6A, 7A illustrate and describe examples of electrically coupling the die 102 to the contacts 132 the package substrate 106. In some such implementations, the method 800 also includes, before said applying the encapsulant, electrically coupling the second die to the second contacts of the second substrate. For example, Stage 1 of FIGS. 4A and 6A illustrate and describe examples of electrically coupling the die 104 to the contacts 134 of the package substrate 108 or the contacts 614 of the package substrate 602. Alternatively, the method 800 may include, after said applying the encapsulant, electrically coupling the second die to the second contacts of the second substrate. For example, Stage 5 of FIGS. 5C and 7C describe that, after formation of the package 200, the die 104 may be disposed in the region 202 and electrically coupled to the contacts 134 of the package substrate 108 or the contacts 714 of the package substrate 702.

In some embodiments, electrically coupling the third set of interconnects between the first substrate and the second substrate includes electrically coupling the third set of interconnects to a second side of the first substrate and to the first side of the second substrate. For example, Stage 2 of FIGS. 4A and 5A illustrate and describe examples of electrically coupling the interconnects 116 between the contacts 129 included in the side 120 of the package substrate 106 and the contacts 135 included in the side 122 of the package substrate (or to the contacts 615 included in the side 608 of the package substrate 602 as shown in FIG. 6C or to the contacts 715 included in the side 708 of the package substrate 702 as shown in FIG. 7C). In such embodiments, the second side of the first substrate is opposite to the first side of the first substrate.

In some embodiments, the method 800 also includes, prior to electrically coupling the third set of interconnects between the first substrate and the second substrate: electrically coupling the first set of interconnects to the first substrate and electrically coupling the second set of interconnects to the second substrate. For example, Stage 1 of FIGS. 4A, 5A, 6A, 7A illustrate and describe examples of the interconnects 112 being electrically coupled to the package substrate 106, and in some embodiments, the interconnects 114 can be electrically coupled to the package substrate 108 during this stage. Alternatively, the method 800 can include, after said electrically coupling the third set of interconnects between the first substrate and the second substrate, electrically coupling the second set of interconnects to the second substrate. For example, Stage 5 of FIGS. 4C, 5C, 6C, 7C illustrate and describe examples of electrically coupling the interconnects 114 to the package substrate 108 (or the package substrates 602, 702).

### Exemplary Electronic Devices

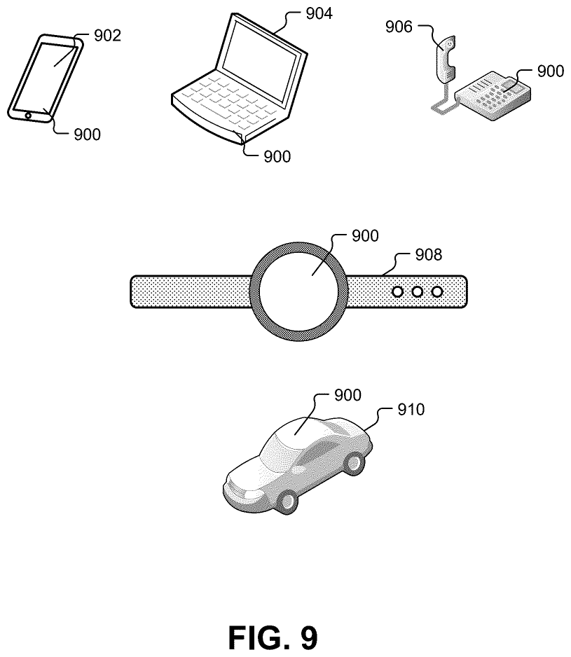

FIG. 9 illustrates various electronic devices that may include or be integrated with any of the packages 100, 200, 300, 640, 740 for side-by-side dies and overlapping interconnected substrates of any of FIGS. 1-3, 4C, 5C, 6C, 7C. For example, a mobile phone device 902, a laptop computer device 904, a fixed location terminal device 906, a wearable device 908, or a vehicle 910 (e.g., an automobile or an aerial device) may include a device 900. The device 900 can include, for example, any of the packages 100, 200, 300, 640, 740 described herein. The devices 902, 904, 906 and 908 and the vehicle 910 illustrated in FIG. 9 are merely exemplary. Other electronic devices may also feature the device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-9 may be rearranged and/or combined into a single component, process, feature or function or embodied in several components, processes, or functions. Additional elements, components, processes, and/or functions may also be added without departing from the disclosure. It should also be noted FIGS. 1-9 and its corresponding description in the present disclosure is not limited to dies and/or ICs. In some implementations, FIGS. 1-9 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately ‘value X’”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the terms “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a package includes a first substrate comprising a first set of conductors that define first contacts for a first die; a second substrate comprising a second set of conductors that define second contacts for a second die; a first set of interconnects electrically coupled to the first substrate; a second set of interconnects electrically coupled to the second substrate; a third set of interconnects electrically coupled to and disposed between the first substrate and the second substrate; and an encapsulant that at least partially surrounds the first substrate, the second substrate, and the third set of interconnects.

Example 2 includes the package of Example 1, where: the encapsulant is configured to retain the first substrate and the second substrate in position relative to one another in a side-by-side configuration in which a first portion of the first substrate overlaps a second portion of the second substrate; and the third set of interconnects are disposed between the first portion of the first substrate and the second portion of the second substrate.

Example 3 includes the package of Example 1 or Example 2, including: the first die electrically coupled to the first contacts; and the second die electrically coupled to the second contacts.

Example 4 includes the package of Example 3, where the second contacts are arranged according to a Joint Electron Device Engineering Council (JEDEC) Solid State Technology Association specification for double data rate (DDR) dynamic random access memory (DRAM) interconnection.

Example 5 includes the package of Example 3, where: the first die includes a first chiplet; and the second die includes a second chiplet.

Example 6 includes the package of Example 4 or Example 5, where the first die comprises one or more processor cores and the second die comprises one or more memory cells accessible to the one or more processor cores via the third set of interconnects.

Example 7 includes the package of any of Examples 1 to 6, where: the first set of interconnects comprise first ball grid array (BGA) balls, the second set of interconnects comprise second BGA balls, the third set of interconnects comprise microbumps, and the microbumps electrically interconnect the first die and the second die.

Example 8 includes the package of any of Examples 1 to 7, where a first pitch associated with the first set of interconnects is greater than a second pitch associated with the second set of interconnects, and where the second pitch is greater than a third pitch associated with the third set of interconnects.

Example 9 includes the package of any of Examples 1 to 8, where: the first substrate includes one or more laminate layers and the second substrate includes one or more redistribution layers; or the first substrate includes one or more laminate layers and the second substrate includes one or more laminate layers.

Example 10 includes the package of any of Examples 1 to 8, where a first thickness of the first substrate is greater than a second thickness of the second substrate.

Example 11 includes the package of any of Examples 1 to 10, where the first substrate includes a first set of layers that have a first layer count, and where the second substrate includes a second set of layers that have a second layer count that is the same as the first layer count.

Example 12 includes the package of any of Examples 1 to 11, including: a third substrate comprising a third set of conductors that define third contacts for a third die; a fourth set of interconnects electrically coupled to the third substrate; and a fifth set of interconnects disposed between and electrically coupled to the first substrate and the third substrate, where the encapsulant at least partially surrounds the third substrate and the fifth set of interconnects.

Example 13 includes the package of Example 12, including: a fourth substrate comprising a fourth set of conductors that define fourth contacts for a fourth die; a sixth set of interconnects electrically coupled to the fourth substrate; and a seventh set of interconnects disposed between and electrically coupled to the first substrate and the fourth substrate, where the encapsulant at least partially surrounds the fourth substrate and the seventh set of interconnects.

Example 14 includes the package of any of Examples 1 to 13, where the first substrate, the second substrate, the first set of interconnects, the second set of interconnects, the third set of interconnects, and the encapsulant are integrated within a mobile device, a hand-held personal communication system (PCS) unit, a portable data unit, a global positioning system (GPS) enabled device, a navigation device, a set top box, a music player, a video player, an entertainment unit, a fixed location data unit, a communications device, a smartphone, a tablet computer, a computer, a wearable device, an Internet of things (IoT) device, a server, a router, a vehicle, or a combination thereof.

According to Example 15, a method of fabrication includes: providing a first substrate and a second substrate, the first substrate comprising a first set of conductors that define first contacts for a first die and the second substrate comprising a second set of conductors that define second contacts for a second die; electrically coupling a third set of interconnects between the first substrate and the second substrate, wherein a first set of interconnects are coupled to the first substrate, and wherein a second set of interconnects are coupled to the second substrate; and applying an encapsulant to at least partially surround the first substrate, the second substrate, and the third set of interconnects.

Example 16 includes the method of Example 15, including, before said applying the encapsulant: electrically coupling the first die to the first contacts of the first substrate; and electrically coupling the second die to the second contacts of the second substrate.

Example 17 includes the method of Example 15, including: before said applying the encapsulant, electrically coupling the first die to the first contacts of the first substrate; and after said applying the encapsulant, electrically coupling the second die to the second contacts of the second substrate.

Example 18 includes the method of any of Examples 15 to 17, where: a portion of the first substrate overlaps a portion of the second substrate; and the third set of interconnects is coupled between the portion of the first substrate and the portion of the second substrate.

Example 19 includes the method of any of Examples 15 to 18, where: a first side of the first substrate includes the first contacts; a first side of the second substrate includes the second contacts; said electrically coupling the third set of interconnects between the first substrate and the second substrate includes electrically coupling the third set of interconnects to a second side of the first substrate and to the first side of the second substrate; and the second side of the first substrate is opposite to the first side of the first substrate.

Example 20 includes the method of any of Examples 15 to 19, including: prior to said electrically coupling the third set of interconnects between the first substrate and the second substrate, electrically coupling the first set of interconnects to the first substrate; and after said electrically coupling the third set of interconnects between the first substrate and the second substrate, electrically coupling the second set of interconnects to the second substrate.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A package comprising:
a first substrate comprising a first set of conductors that define first contacts for a first die;
a second substrate comprising a second set of conductors that define second contacts for a second die;
a first set of interconnects electrically coupled to the first substrate;
a second set of interconnects electrically coupled to the second substrate;
a third set of interconnects electrically coupled to and disposed between the first substrate and the second substrate; and
an encapsulant that at least partially surrounds the first substrate, the second substrate, and the third set of interconnects.

2. The package of claim 1, wherein:
the encapsulant is configured to retain the first substrate and the second substrate in position relative to one another in a side-by-side configuration in which a first portion of the first substrate overlaps a second portion of the second substrate; and
the third set of interconnects are disposed between the first portion of the first substrate and the second portion of the second substrate.

3. The package of claim 1, further comprising:
the first die electrically coupled to the first contacts; and
the second die electrically coupled to the second contacts.

4. The package of claim 3, wherein the second contacts are arranged according to a Joint Electron Device Engineering Council (JEDEC) Solid State Technology Association specification for double data rate (DDR) dynamic random access memory (DRAM) interconnection.

5. The package of claim 3, wherein:
the first die includes a first chiplet; and
the second die includes a second chiplet.

6. The package of claim 3, wherein the first die comprises one or more processor cores and the second die comprises one or more memory cells accessible to the one or more processor cores via the third set of interconnects.

7. The package of claim 1, wherein:
the first set of interconnects comprise first ball grid array (BGA) balls,
the second set of interconnects comprise second BGA balls,
the third set of interconnects comprise microbumps, and
the microbumps electrically interconnect the first die and the second die.

8. The package of claim 1, wherein a first pitch associated with the first set of interconnects is greater than a second pitch associated with the second set of interconnects, and wherein the second pitch is greater than a third pitch associated with the third set of interconnects.

9. The package of claim 1, wherein:
the first substrate includes one or more laminate layers and the second substrate includes one or more redistribution layers; or
the first substrate includes one or more laminate layers and the second substrate includes one or more laminate layers.

10. The package of claim 1, wherein a first thickness of the first substrate is greater than a second thickness of the second substrate.

11. The package of claim 1, wherein the first substrate includes a first set of layers that have a first layer count, and wherein the second substrate includes a second set of layers that have a second layer count that is the same as the first layer count.

12. The package of claim 1, further comprising:
a third substrate comprising a third set of conductors that define third contacts for a third die;
a fourth set of interconnects electrically coupled to the third substrate; and
a fifth set of interconnects disposed between and electrically coupled to the first substrate and the third substrate,
wherein the encapsulant at least partially surrounds the third substrate and the fifth set of interconnects.

13. The package of claim 11, further comprising:
a fourth substrate comprising a fourth set of conductors that define fourth contacts for a fourth die;
a sixth set of interconnects electrically coupled to the fourth substrate; and
a seventh set of interconnects disposed between and electrically coupled to the first substrate and the fourth substrate,
wherein the encapsulant at least partially surrounds the fourth substrate and the seventh set of interconnects.

14. The package of claim 1, wherein the first substrate, the second substrate, the first set of interconnects, the second set of interconnects, the third set of interconnects, and the encapsulant are integrated within a mobile device, a hand-held personal communication system (PCS) unit, a portable data unit, a global positioning system (GPS) enabled device, a navigation device, a set top box, a music player, a video player, an entertainment unit, a fixed location data unit, a communications device, a smartphone, a tablet computer, a computer, a wearable device, an Internet of things (IoT) device, a server, a router, a vehicle, or a combination thereof.

15. A method of fabrication, the method comprising:
providing a first substrate and a second substrate, the first substrate comprising a first set of conductors that define first contacts for a first die and the second substrate comprising a second set of conductors that define second contacts for a second die;
electrically coupling a third set of interconnects between the first substrate and the second substrate, wherein a first set of interconnects are coupled to the first substrate, and wherein a second set of interconnects are coupled to the second substrate; and
applying an encapsulant to at least partially surround the first substrate, the second substrate, and the set of interconnects.

16. The method of claim 15, further comprising, before said applying the encapsulant:
electrically coupling the first die to the first contacts of the first substrate; and
electrically coupling the second die to the second contacts of the second substrate.

17. The method of claim 15, further comprising:
before said applying the encapsulant, electrically coupling the first die to the first contacts of the first substrate; and
after said applying the encapsulant, electrically coupling the second die to the second contacts of the second substrate.

18. The method of claim 15, wherein:
a portion of the first substrate overlaps a portion of the second substrate; and
the third set of interconnects is coupled between the portion of the first substrate and the portion of the second substrate.

19. The method of claim 15, wherein:
a first side of the first substrate includes the first contacts;
a first side of the second substrate includes the second contacts;
said electrically coupling the third set of interconnects between the first substrate and the second substrate includes electrically coupling the third set of interconnects to a second side of the first substrate and to the first side of the second substrate; and
the second side of the first substrate is opposite to the first side of the first substrate.

20. The method of claim 15, further comprising:
prior to said electrically coupling the third set of interconnects between the first substrate and the second substrate, electrically coupling the first set of interconnects to the first substrate; and
after said electrically coupling the third set of interconnects between the first substrate and the second substrate, electrically coupling the second set of interconnects to the second substrate.
